(19) United States
(12) Patent Application Publication
(10) Pub. No.: US 2013/0062614 A1
(43) Pub. Date: Mar. 14, 2013

(54) GROUP III-V ENHANCEMENT MODE TRANSISTOR WITH THYRISTOR GATE

(71) Applicants: Naveen Tipirneni, Plano, TX (US); Sameer Pendharkar, Allen, TX (US)

(72) Inventors: Naveen Tipirneni, Plano, TX (US); Sameer Pendharkar, Allen, TX (US)

(73) Assignee: Texas Instruments Incorporated, Dallas, TX (US)

(21) Appl. No.: 13/591,140

(22) Filed: Aug. 21, 2012

Related U.S. Application Data
(60) Provisional application No. 61/532,866, filed on Sep. 9, 2011.

(51) Int. Cl. H01L 29/70; H01L 21/20; H01L 29/20

(52) U.S. Cl. 257/76; 438/478; 257/192; 257/E29.089; 257/E21.09; 257/E29.171

(57) ABSTRACT

An apparatus includes an enhancement mode transistor having multiple Group III-V layers above a substrate and a gate above the Group III-V layers. The gate includes multiple layers of material that form at least a portion of a thyristor. The multiple layers of material may include a first p-type layer of material, an n-type layer of material on the first p-type layer, and a second p-type layer of material on the n-type layer. The multiple layers of material may also include a p-type layer of material, an n-type layer of material on the p-type layer, and a Schottky metal layer on the n-type layer. The enhancement mode transistor may represent a high electron mobility transistor (HEMT) or a heterostructure field effect transistor (HFET).

### CROSS-REFERENCE TO RELATED APPLICATION AND PRIORITY CLAIM

This application claims priority under 35 U.S.C. §119(e) to U.S. Provisional Patent Application No. 61/532,866 filed on Sep. 9, 2011, which is hereby incorporated by reference.

### TECHNICAL FIELD

This disclosure is generally directed to integrated circuits. More specifically, this disclosure is directed to a Group III-V enhancement mode transistor with a thyristor gate.

### BACKGROUND

Gallium nitride (GaN) and other “Group III-V” compounds can be used in manufacturing high-speed or high-power integrated circuit devices. Gallium nitride is often desirable because it can withstand high operating temperatures and can provide high breakdown voltages compared to standard silicon devices. Gallium nitride can also typically provide good high-frequency performance and provide lower on-resistances.

### SUMMARY

This disclosure provides a Group III-V enhancement mode transistor with a thyristor gate.

In a first embodiment, an apparatus includes an enhancement mode transistor having multiple Group III-V layers above a substrate and a gate above the Group III-V layers. The gate includes multiple layers of material that form at least a portion of a thyristor.

In a second embodiment, a method of forming an enhancement mode transistor includes forming multiple Group III-V layers above a substrate and forming a gate above the Group III-V layers. The gate includes multiple layers of material that form at least a portion of a thyristor.

In a third embodiment, a circuit includes multiple enhancement mode transistors. Each enhancement mode transistor includes multiple Group III-V layers above a substrate and a gate above the Group III-V layers, where the gate includes multiple layers of material that form at least a portion of a thyristor.

Other technical features may be readily apparent to one skilled in the art from the following figures, descriptions, and claims.

### BRIEF DESCRIPTION OF THE DRAWINGS

For a more complete understanding of this disclosure and its features, reference is now made to the following description, taken in conjunction with the accompanying drawings, in which:

FIG. 1 illustrates an example Group III-V enhancement mode transistor with a thyristor gate in accordance with this disclosure;

FIGS. 2A through 21 illustrate an example fabrication technique for forming a Group III-V enhancement mode transistor with a thyristor gate in accordance with this disclosure; and

FIG. 3 illustrates an example method for forming a Group III-V enhancement mode transistor with a thyristor gate in accordance with this disclosure.

### DETAILED DESCRIPTION

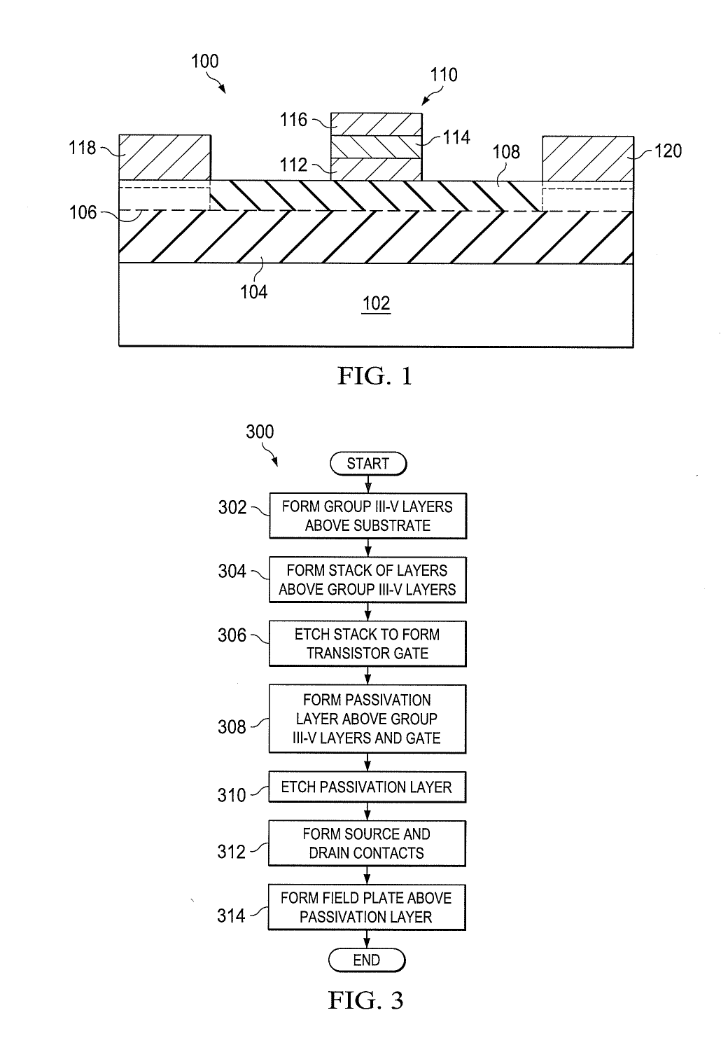

FIGS. 1 through 3, discussed below, and the various embodiments used to describe the principles of the present invention in this patent document are by way of illustration only and should not be construed in any way to limit the scope of the invention. Those skilled in the art will understand that the principles of the present invention may be implemented in any suitable manner and in any type of suitably arranged device or system.

FIG. 1 illustrates an example Group III-V enhancement mode transistor 100 with a thyristor gate in accordance with this disclosure. As shown in FIG. 1, the transistor 100 includes a substrate 102. The substrate 102 includes any suitable semiconductor substrate that supports or carries other components of the transistor 100. The substrate 102 could, for example, include a silicon, sapphire, or silicon carbide wafer or other substrate.

One or more Group III-V layers 104 are formed above the substrate 102. In some embodiments, the Group III-V layers 104 include multiple layers, such as a transition layer, a buffer layer, an insulating layer, and an unintentionally-doped channel layer. The transition layer could help in the formation of the buffer layer above the substrate 102. The buffer layer can help to accommodate thermal and lattice mismatch between the substrate 102 and the Group III-V layers in the transistor 100.

An optional Group III-V layer 106 can be formed above the Group III-V layers 104, and a Group III-V barrier layer 108 is formed above the Group III-V layers 104. The layer 106 can help in the formation of the barrier layer 108. The barrier layer 108 is used to form a portion of at least one semiconductor device, such as a Group III-V-based field effect transistor (FET) or high electron mobility transistor (HEMT) (also known as a heterostructure FET or HFET). The barrier layer 108 could include or form a part of any other or additional integrated circuit component(s).

Each Group III-V layer 104-108 could be formed from any suitable Group III-V compound. A “Group III-V compound” refers to a compound formed using at least one Group III element and at least one Group V element. Example Group III elements include indium, gallium, and aluminum. Example Group V elements include nitrogen, arsenic, and phosphorus. Example Group III-V compounds include gallium nitride (GaN), aluminum gallium nitride (AlGaN), indium aluminum nitride (InAlN), indium aluminum gallium nitride (InAlGaN), aluminum nitride (AlN), indium nitride (InN), and indium gallium nitride (InGaN). Other example Group III-V compounds include gallium arsenide (GaAs), aluminum gallium arsenide (AlGaAs), indium phosphide (InP), and indium gallium phosphide (InGaP). In particular embodiments, the layers 104 include an aluminum nitride transition layer, an aluminum gallium nitride buffer layer, and a gallium nitride channel layer. Also, in particular embodiments, the layer 106 includes an aluminum nitride layer, and the barrier layer 108 includes an aluminum gallium nitride layer.

Each of the Group layers 104-108 could also be formed in any suitable manner. For example, the Group III-V layers 104-108 could include epitaxial layers grown using metal-organic chemical vapor deposition (MOCVD), Molecular Beam Epitaxy (MBE), or other technique. In addition, each of the Group III-V layers 104-108 could have any suitable thickness(es).

Additional components can be used to complete formation of at least one Group III-V semiconductor device. For example, an upper portion of the barrier layer 108 could be doped with one or more dopants to create a source, a drain, or other transistor regions. Also, a gate 110 is formed above the barrier layer 108 using a stack of layers 112-116. In addition, source and drain contacts 118-120 are formed in contact with at least one of the Group III-V layers 104-108. Connections to other devices or circuit elements could be made using the contacts 118-120 and the gate 110.

Each of the contacts 118-120 includes any suitable conductive structure providing electrical connection to the transistor 100. Each of the contacts 118-120 could also be formed in any suitable manner. For instance, a stack of metal layers could be deposited, etched, and annealed to form Ohmic contacts. Note that the position(s) of the contacts 118-120 could vary. In FIG. 1, the contacts 118-120 are shown as residing on top of the barrier layer 108. However, the barrier layer 108 could be partially or completely etched through, and the contacts 118-120 could be formed partially within the barrier layer 108 or on top of the Group III-V layers 104. The exact etch depth into the barrier layer 108 can be optimized to achieve the lowest possible contact resistance. For an aluminum gallium nitride barrier layer 108, the optimal etch depth could depend on the AlN mole fraction and the thickness of the barrier layer 108.

In conventional enhancement mode Group III-nitride HEMTs, a p-type layer of material is often used as the gate in the transistor. The p-type layer of material and an underlying Group III-nitride material form a p-n junction. However, under ON-state conditions when a positive voltage is applied to the p-n junction, the gate can turn on at a relatively low voltage, such as about 3-4V. This can result in increased gate leakage. Also, since the gate voltage rating limitation is often low (such as less than 5V), this limits the maximum positive voltage that can applied to the gate, leading to gate overdrive voltage limitations and hence under-performing transistors. In addition, conventional silicon FETs often have high gate-to-source voltages (such as about 20V) with high threshold voltages (such as higher than 2V). Integrated circuit drivers that are used with these conventional silicon FETs often cannot be used with conventional enhancement mode Group III-nitride HEMTs.

In accordance with this disclosure, the gate 110 is designed to help overcome these types of problems. In this example, the gate 110 is formed from the stack of layers 112-116. The stack forms multiple junctions, such as two p-n junctions or one p-n junction and one metal-semiconductor (Schottky) junction arranged back-to-back. The junctions and the barrier layer 108 form a thyristor. The use of back-to-back junctions helps to prevent gate leakage increases in the transistor 100 when positive voltages are applied to the gate 110. Moreover, the gate voltage rating limitation of the transistor 100 can be larger than conventional HEMTs, reducing the need for gate overdrive voltage limitations and providing improved transistor performance. In addition, the transistor 100 can be used with integrated circuit drivers normally used with silicon FETs.

Any suitable materials can be used to form the layers 112-116 of the gate 110. In some embodiments, the layers 112 and 116 include p-type gallium nitride or other p-type Group III-V compound(s), while the layer 114 includes n-type gallium nitride or other n-type Group III-V compound(s). In other embodiments, the layer 112 includes p-type gallium nitride or other p-type Group III-V compound(s), the layer 114 includes n-type gallium nitride or other n-type Group III-V compound(s), and the layer 116 includes a Schottky metal layer (which forms a Schottky barrier at the metal-semiconductor junction with the layer 114). In general, the gate 110 can include any suitable materials forming back-to-back junctions of a thyristor. Also, the gate 110 can be formed in any suitable manner, such as by depositing layers of material above the barrier layer 108 and etching the layers using a metal or other mask.

Although FIG. 1 illustrates one example of a Group III-V enhancement mode transistor 100 with a thyristor gate, various changes may be made to FIG. 1. For example, any suitable materials and processes could be used to form various layers or other structures of the transistor 100. Also, the relative sizes and shapes of the components in FIG. 1 and the arrangements of those components in FIG. 1 are for illustration only. In addition, an integrated circuit could include one or multiple instances of the transistor 100.

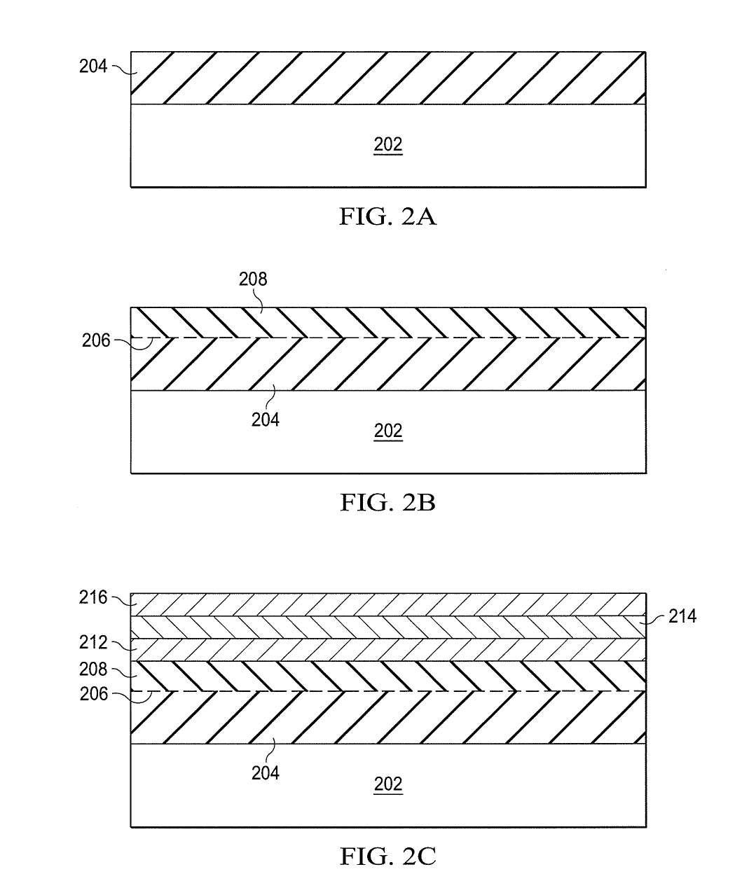

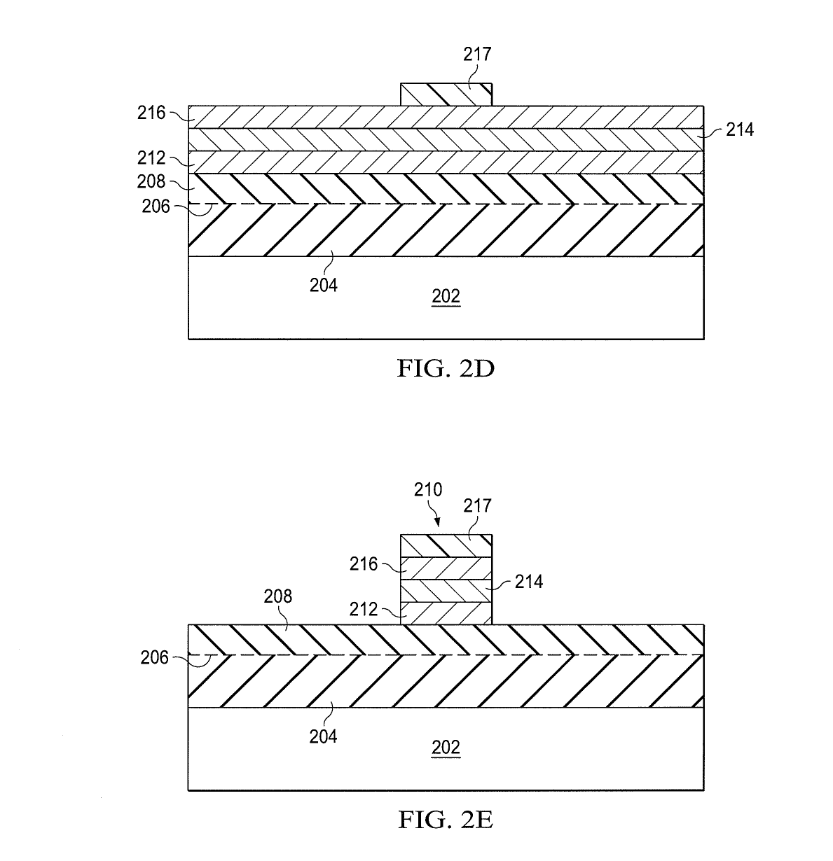

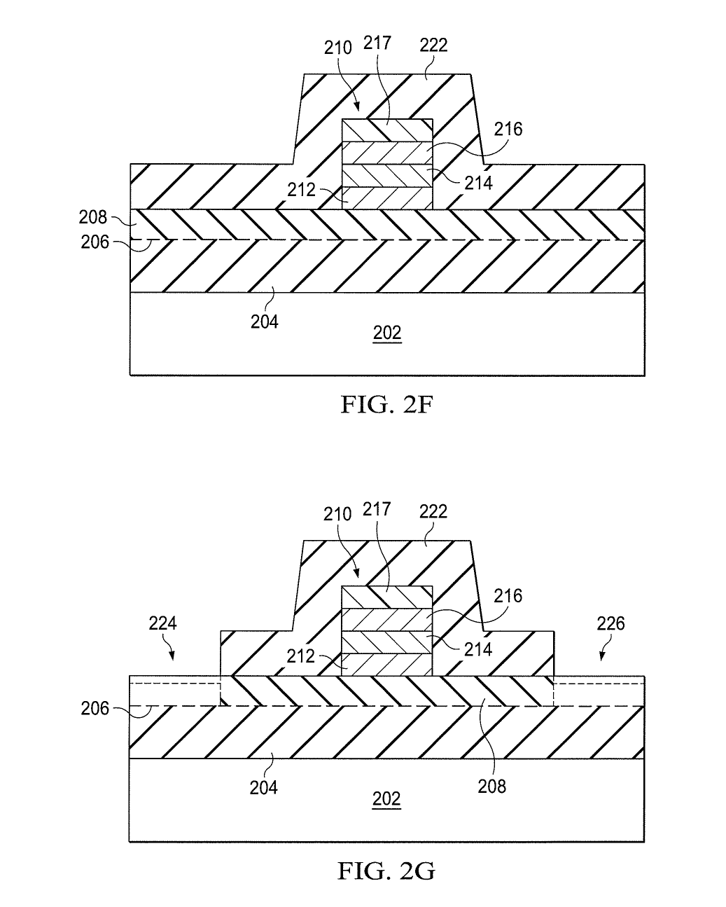

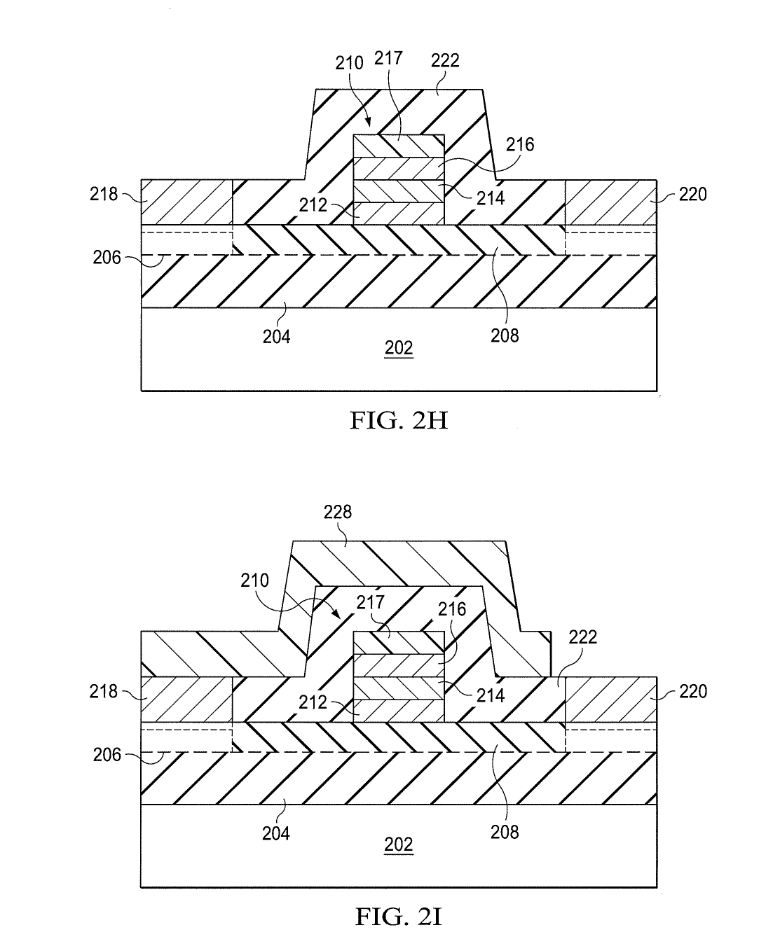

FIGS. 2A through 2I illustrate an example fabrication technique for forming a Group III-V enhancement mode transistor with a thyristor gate in accordance with this disclosure. As shown in FIG. 2A, a substrate 202 is fabricated or provided. The substrate 202 could include any suitable semiconductor substrate, such as a silicon, silicon carbide, or sapphire wafer. One or more Group III-V layers 204 are formed above the substrate 202. This could include, for example, forming a transition layer, a buffer layer, an insulating layer, and a channel layer. Each layer could be formed from any suitable Group III-V compound(s). Each layer could be formed epitaxially or in any other suitable manner. Each layer could also have any suitable thickness(es).

As shown in FIG. 2B, a barrier layer 208 is formed above the Group III-V layers 204, possibly with the assistance of an optional layer 206. Each layer 206-208 could be formed from any suitable Group III-V compound(s). Each layer 206-208 could be formed epitaxially or in any other suitable manner, and each layer 206-208 could have any suitable thickness(es).

As shown in FIG. 2C, three layers 212-216 are formed above the barrier layer 208. These layers 212-216 include the materials that will help form a thyristor gate for the transistor being fabricated. As noted above, these layers 212-216 could be formed from any suitable materials. For example, the layers 212-216 could form a p-type gallium nitride/n-type gallium nitride/p-type gallium nitride stack or a p-type gallium nitride/n-type gallium nitride/Schottky metal stack. Each layer 212-216 could be formed in any suitable manner and can have any suitable thickness(es).

As shown in FIG. 2D, a mask 217 is formed above the stack of layers 212-216. The mask 217 defines the portions of the layers 212-216 that will be removed to form the thyristor gate of the transistor. The mask 217 can be formed from any suitable material(s), such as metal. Also, the mask 217 can be formed in any suitable manner, such as by depositing a layer of metal and patterning the metal layer.

As shown in FIG. 2E, the layers 212-216 are etched to form a gate 210 of the transistor. The gate 210 includes the remaining portions of the layers 212-216. The layers 212-216 can be etched using any suitable etch process, such as a wet or dry etch. Note that a slight over-etching into the underlying barrier layer 208 may or may not occur here.

As shown in FIG. 2F, a passivation layer 222 is formed above the barrier layer 208 and the gate 210. The passivation layer 222 could be formed from any suitable material(s), such as an oxide. The passivation layer 222 could also be formed in any suitable manner, such as chemical or physical vapor deposition. In addition, the passivation layer 222 could have any suitable thickness(es).

As shown in FIG. 2G, areas 224-226 of the passivation layer 222 are removed, such as through an etch process. This could occur in any suitable manner, such as by masking the passivation layer 222 and removing exposed portions of the passivation layer 222 in the areas 224-226. Note that the etch performed here could stop at the top surface of the barrier layer 208. Alternatively, the etch could extend partially through the barrier layer 208, or the etch could extend completely through the barrier layer 208 to expose the top surface of the underlying Group III-V layers 204.

As shown in FIG. 2H, source and drain contacts 218-220 are formed in the areas 224-226. The contacts 218-220 include any suitable electrical contacts, such as Ohmic contacts. The contacts 218-220 can be formed from any suitable material(s) and in any suitable manner. For instance, multiple layers of metal could be deposited within the areas 224-226 and above the passivation layer 222. A mask could then be formed above the metal layers and used to etch the metal layers, leaving portions of the metal layers in the areas 224-226. Finally, the metal layers could be annealed to form the Ohmic contacts.

As shown in FIG. 2I, a field plate 228 is formed above the passivation layer 222. The field plate 228 could be formed from any suitable material(s), such as metal. The field plate 228 could also be formed in any suitable manner. For example, the field plate 228 in FIG. 2I could be formed at the same time as the source and drain contacts 218-220 in FIG. 2H. As a particular example, the metal layers deposited and used to form Ohmic contacts could be etched to leave portions of the metal layers that form the field plate 228. In other embodiments, the field plate 228 can be formed separate from the source and drain contacts 218-220. For instance, the passivation layer 222 can be etched to provide access to the gate, source, and drain regions as needed in the device (not shown in this cross-section but done at some point in the third dimension perpendicular to the page). A metallization layer (such as a “metal 1” layer) can then be deposited and etched to form the field plate 228. The metallization layer could also be used to connect the source and drain contacts and/or gates of multiple transistor cells to form a single larger device of needed size.

Although FIGS. 2A through 2I illustrate one example of a fabrication technique for forming a Group III-V enhancement mode transistor with a thyristor gate, various changes may be made to FIGS. 2A through 21. For example, each element in this structure could be fabricated using any suitable material(s) and any suitable technique(s). Also, the relative sizes and shapes of the elements in this structure could be modified according to particular needs. In addition, additional components could be formed within the structure.

FIG. 3 illustrates an example method 300 for forming a Group III-V enhancement mode transistor with a thyristor gate in accordance with this disclosure. As shown in FIG. 3, one or more Group III-V layers are formed above a substrate at step 302. This could include, for example, forming a transition layer, a buffer layer, an insulating layer, a channel layer, and a barrier layer over a silicon or other substrate. Each layer could be formed epitaxially or in any other suitable manner from any suitable Group III-V material(s), and each layer could have any suitable thickness(es).

A stack of layers is formed above the Group III-V layers at step 304. This could include, for example, forming a p-type layer/n-type layer/p-type layer stack or a p-type layer/n-type layer/Schottky metal stack. Each layer could be formed in any suitable manner and can have any suitable thickness(es). The stack is etched to form a transistor gate at step 306. This could include, for example, forming a metal mask or other mask above the stack and etching the stack.

A passivation layer is formed above the Group III-V layers and the transistor gate at step 308. The passivation layer could be formed from any suitable material(s) and in any suitable manner. The passivation layer is etched at step 310. This could include, for example, etching the passivation layer in areas where source and drain contacts are to be formed.

The source and drain contacts are formed at step 312, and a field plate above the passivation layer is formed at step 314. This could include, for example, depositing multiple metal layers, etching the metal layers, and annealing the remaining portions of the metal layers to form Ohmic contacts. The field plate could be formed during formation of the source and drain contacts, or the field plate could be formed at a different time.

Although FIG. 3 illustrates one example of a method 300 for forming a Group III-V enhancement mode transistor with a thyristor gate, various changes may be made to FIG. 3. For example, while shown as a series of steps, various steps in FIG. 3 could overlap, occur in parallel, occur in a different order, or occur multiple times. Also, note that additional operations may occur to complete formation of an integrated circuit that uses the transistor.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C. The term “on” means in direct contact with, while the term “above” encompasses either “on” or separated by one or more intervening materials.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
an enhancement mode transistor comprising:
multiple Group III-V layers above a substrate; and
a gate above the Group III-V layers;
wherein the gate comprises multiple layers of material that form at least a portion of a thyristor.

2. The apparatus of claim 1, wherein the multiple layers of material comprise:
a first p-type layer of material;
an n-type layer of material on the first p-type layer; and
a second p-type layer of material on the n-type layer.

3. The apparatus of claim 2, wherein:
the first and second p-type layers comprise p-type gallium nitride; and
the n-type layer comprises n-type gallium nitride.

4. The apparatus of claim 1, wherein the multiple layers of material comprise:
a p-type layer of material;
an n-type layer of material on the p-type layer; and
a Schottky metal layer on the n-type layer.

5. The apparatus of claim 4, wherein:
the p-type layer comprises p-type gallium nitride; and
the n-type layer comprises n-type gallium nitride.

6. The apparatus of claim 1, further comprising:
source and drain contacts in contact with at least one of the Group III-V layers.

7. The apparatus of claim 6, wherein the source and drain contacts comprise Ohmic contacts.

8. The apparatus of claim 1, further comprising:
a passivation layer above the Group III-V layers and the gate; and
a field plate above the passivation layer.

9. The apparatus of claim 1, wherein the enhancement mode transistor comprises a high electron mobility transistor (HEMT) or a heterostructure field effect transistor (HFET).

10. A method of forming an enhancement mode transistor comprising:
forming multiple Group III-V layers above a substrate; and
forming a gate above the Group III-V layers, wherein the gate comprises multiple layers of material that form at least a portion of a thyristor.

11. The method of claim 10, wherein the multiple layers of material comprise:
a first p-type layer of material;
an n-type layer of material on the first p-type layer; and
a second p-type layer of material on the n-type layer.

12. The method of claim 11, wherein:
the first and second p-type layers comprise p-type gallium nitride; and
the n-type layer comprises n-type gallium nitride.

13. The method of claim 10, wherein the multiple layers of material comprise:
a p-type layer of material;
an n-type layer of material on the p-type layer; and
a Schottky metal layer on the n-type layer.

14. The method of claim 13, wherein:
the p-type layer comprises p-type gallium nitride; and
the n-type layer comprises n-type gallium nitride.

15. The method of claim 10, further comprising:
forming source and drain contacts in contact with at least one of the Group III-V layers.

16. The method of claim 10, further comprising:
forming a passivation layer above the Group III-V layers and the gate; and
forming a field plate above the passivation layer.

17. The method of claim 10, wherein the enhancement mode transistor comprises a high electron mobility transistor (HEMT) or a heterostructure field effect transistor (HFET).

18. A circuit comprising:
multiple enhancement mode transistors, each enhancement mode transistor comprising:
multiple Group III-V layers above a substrate; and
a gate above the Group III-V layers, wherein the gate comprises multiple layers of material that form at least a portion of a thyristor.

19. The circuit of claim 18, wherein the multiple layers of material comprise:
a first p-type layer of material;
an n-type layer of material on the first p-type layer; and
a second p-type layer of material on the n-type layer.

20. The circuit of claim 18, wherein the multiple layers of material comprise:
a p-type layer of material;
an n-type layer of material on the p-type layer; and
a Schottky metal layer on the n-type layer.
